(19) United States
(12) Patent Application Publication
(10) Pub. No.: US 2026/0096396 A1
(43) Pub. Date: Apr. 2, 2026

(54) METHOD OF PREDICTING WAFER OUT TIME

(71) Applicant: United Semiconductor (Xiamen) Co., Ltd., Xiamen (CN)

(72) Inventors: Jia Xiao Meng, Shamen City (CN); Tao Liu, Singapore (SG); Wen Yi Tan, Xiamen (CN)

(73) Assignee: United Semiconductor (Xiamen) Co., Ltd., Xiamen (CN)

(21) Appl. No.: 18/929,595

(22) Filed: Oct. 28, 2024

(30) Foreign Application Priority Data
Sep. 27, 2024 (CN) 202411364844.4

(51) Int. Cl. H01L 21/66

(52) U.S. Cl. CPC H10P 74/00

(57) ABSTRACT

The manufacturing historical data of each lot is collected during each manufacturing step of a manufacturing process for providing a manufacturing data set which is divided into a training data set and a testing data set. A preliminary random forest prediction model is built based on the characteristic values and an initial label of each piece of manufacturing historical data in the training data set. The preliminary random forest prediction model is then evaluated using each piece of manufacturing historical data in the testing data set for building an optimized random forest prediction model. The estimated start/end time of each manufacturing step in the manufacturing process may be acquired by inputting new data into the optimized random forest prediction model. The cycle time and turn rate of the manufacturing process may thus be optimized.

### BACKGROUND OF THE INVENTION

### 1. Field of the Invention

The present invention is related to a method of predicting wafer out time, and more particularly, to a method of predicting wafer out time during semiconductor manufacturing processes using random forest algorithm.

### 2. Description of the Prior Art

A semiconductor is a material that is between conductor and insulator in ability to conduct electrical current. The conducting properties of semiconductor material may be altered by introducing impurities and by the application of electrical fields. A semiconductor device is an electronic component made of semiconductor material, such as diode, transistor, resistor and capacitor. During semiconductor manufacturing processes, an integrated circuit (IC) may be fabricated by forming many interconnected semiconductor devices on a silicon chip, thereby performing various functions such as controlling, processing and storing information.

A semiconductor manufacturing process is generally split into two main stages: the front-end process and the back-end process. The front-end process is focused on wafer fabrication, wherein semiconductor devices, such as resistors, capacitors, diodes and transistors, and their interconnections may be formed on a silicon wafer by means of photolithography, etching, deposition, ion implantation and polishing. The back-end process involves the assembly of an integrated circuit and generally includes dicing, testing and packaging stages.

The fabrication of a wafer normally includes 500-100 highly interdependent manufacturing steps. Cycle time is the amount of time it takes to process a wafer lot in a fab from start to finish. A prior art method of predicting wafer out time is based on the average cycle time of each manufacturing step and the product layer count. The prior art method is simple, but far from accurate. Therefore, there is a need for a method of accurately predicting wafer out time during semiconductor manufacturing processes.

### SUMMARY OF THE INVENTION

The present invention provides a method of predicting wafer out time. Manufacturing historical data of each lot is collected during each manufacturing step of a manufacturing process for providing a manufacturing data set. The manufacturing data set is then divided into a training data set and a testing data set. A preliminary random forest prediction model is built based on M characteristic values and an initial label of each piece of manufacturing historical data in the training data set, wherein M is an integer larger than 1. Each piece of manufacturing historical data in the testing data set is inputted into the preliminary random forest prediction model for acquiring a prediction label of each piece of manufacturing historical data in the testing data set. An optimized random forest prediction model associated with the preliminary random forest prediction model is built based on the initial label and the prediction label of each piece of manufacturing historical data in the testing data set. New data is inputted into the optimized random forest prediction model for acquiring an estimated start time and/or an estimated end time of each lot during each manufacturing step in the manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a method of predicting wafer out time according to an embodiment of the present invention.

FIG. 2 is a diagram illustrating the manufacturing data set provided by the present method according to an embodiment of the present invention

FIG. 3 is a diagram illustrating the sample data sets acquired by the present method according to an embodiment of the present invention

FIGS. 4A-4D are diagrams illustrating decision models acquired by the present method according to an embodiment of the present invention.

FIG. 5 is a diagram illustrating the prediction label of each piece of manufacturing historical data in the testing data set acquired by the present method according to an embodiment of the present invention.

FIG. 6 is a diagram illustrating the estimated start time and/or the estimated end time of each manufacturing step in the manufacturing process acquired by the present method according to an embodiment of the present invention.

FIG. 7 is a state diagram illustrating each stage when performing the present method of predicting wafer out time according to an embodiment of the present invention.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

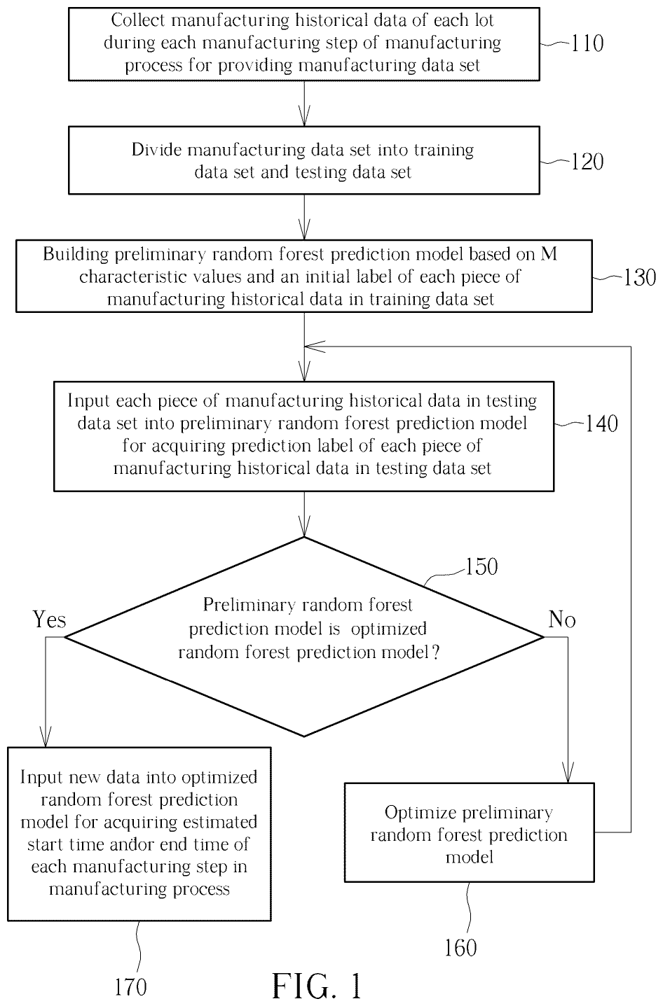

FIG. 1 is a flowchart illustrating a method of predicting wafer out time according to an embodiment of the present invention. The flowchart depicted in FIG. 1 includes the following steps:
Step 110: collect manufacturing historical data of each lot during each manufacturing step of a manufacturing process for providing a manufacturing data set.
Step 120: divide the manufacturing data set into a training data set and a testing data set.
Step 130: build a preliminary random forest prediction model based on M characteristic values and an initial label of each piece of manufacturing historical data in the training data set.
Step 140: input each piece of manufacturing historical data in the testing data set into the preliminary random forest prediction model for acquiring a prediction label of each piece of manufacturing historical data in the testing data set.
Step 150: determine whether the preliminary random forest prediction model is an optimized random forest prediction model by comparing the initial label and the prediction label of each piece of manufacturing historical data in the testing data set? If yes, execute step 170; if no, execute step 160.
Step 160: optimize the preliminary random forest prediction model; execute step 140.
Step 170: input new data into the optimized random forest prediction model for acquiring an estimated start time and/or an estimated end time of each manufacturing step in the manufacturing process.

As well-known to those skilled in the art, a batch of wafers (commonly referred to as “wafer lot”) is processed at the same time instead of casting single wafer in a typical semiconductor manufacturing process. Generally speaking, all wafers in the same lot have the same material composition and manufacturing process, and thus have similar characteristics. In step 110, the manufacturing historical data of each lot during each manufacturing step of the manufacturing process is collected for providing the manufacturing data set. In step 120, the manufacturing data set is then into the training data set and the testing data set.

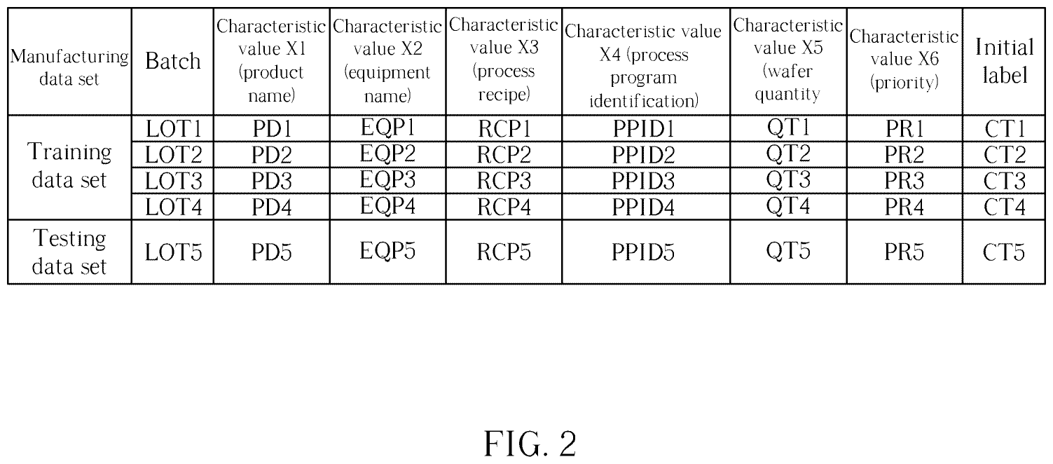

FIG. 2 is a diagram illustrating the manufacturing data set provided after performing steps 110 and 120 according to an embodiment of the present invention. For illustrative purpose, it is assumed that L pieces of manufacturing historical data associated with L lots are collected in step 110, wherein each piece of manufacturing historical data includes P characteristic values and an initial label of a corresponding lot during each manufacturing step of the manufacturing process, and L and P are integers larger than 1. Under such circumstance, the manufacturing data set provided in step 110 may include C pieces of manufacturing historical data each including M characteristic values and an initial label of a corresponding lot during each manufacturing step of the manufacturing process, wherein C is an integer larger than 1 and not larger than L, and M is an integer larger than 1 and not larger than P. For illustrative purpose, it is also assumed that the training data set divided from the manufacturing data set in step 120 includes A pieces of manufacturing historical data, and the testing data set divided from the manufacturing data set in step 120 includes B pieces of manufacturing historical data, wherein A and B are positive integers and A+B=C.

For illustrative purpose, FIG. 2 depicts the embodiment when M=6, A=4, B=1 and C=5. In other words, among the 5 pieces of manufacturing historical data respectively associated with lots LOT1-LOT5 and collected during a specific manufacturing step of the manufacturing process, each piece of the above-mentioned manufacturing historical data includes 6 characteristic values X1-X6. The characteristic value X1 represents the names of the products PD1-PD5 fabricated using the lots LOT1-LOT5 during the specific manufacturing step. The characteristic value X2 represents the names of equipment EQP1-EQP5 which respectively handle the lots LOT1-LOT5 during the specific manufacturing step. The characteristic value X3 represents the process recipes RCP1-RCP5 respectively adopted by the lots LOT1-LOT5 during the specific manufacturing step. The characteristic value X4 represents the process program identifications PPID1-PPID5 of the lots LOT1-LOT5 during the specific manufacturing step. The characteristic value X5 represents the wafer quantities QT1-QT5 of the lots LOT1-LOT5 during the specific manufacturing step. The characteristic value X6 represents the priorities PR1-PR5 of the lots LOT1-LOT5 during the specific manufacturing step. Also, the training data set includes 4 pieces of manufacturing historical data associated with the lots LOT1-LOT4, and the testing data set includes 1 piece of manufacturing historical data associated with the lot LOT5, wherein CT1-CT5 represent the initial labels of the manufacturing historical data associated with the lots LOT1-LOT5, respectively. It is to be noted that the manufacturing data set depicted in FIG. 2 is merely an embodiment of the present invention, and the value of M, A, B or C does not limit the scope of the present invention. In an embodiment, the initial labels CT1-CT5 may be initial cycle times of the lots LOT1-LOT5 during the specific manufacturing step of the manufacturing process, but is not limited thereto.

Since most machine learning algorithms are extremely sensitive to the range and the distribution of data characteristics, each piece of manufacturing historical data may further be pre-processed in step 110 in the present invention.

In an embodiment, a dummy variable processing may be performed on each piece of manufacturing historical data in the manufacturing data set in order to quantize non-quantifiable variables. For example, when a characteristic value is a categorical variable instead of an interval variable or a ratio variable, a dummy variable with a numeric stand-in for a qualitative fact or a logical proposition may be introduced to assist in subsequent data analysis.

In an embodiment, a data normalization processing may be performed on each piece of manufacturing historical data in the manufacturing data set for organizing data entries so as to ensure they appear similar across all fields and records, thereby assisting in subsequent data analysis.

In step 130, the preliminary random forest prediction model may be built based on the M characteristic values and the initial label of each piece of manufacturing historical data in the training data set. More specifically, in the present invention, the training data set may be analyzed using random forest algorithm for building the preliminary random forest prediction model. Random forest algorithm is a supervised learning regression method and bagging technique that uses an ensemble of decision trees to predict continuous target variables. First, N sample data sets are selected from the training data set using a bootstrap aggregating method, wherein each sample data set includes n pieces of manufacturing historical data, and N and n are integers larger than 1. Next, m predetermined characteristic values are selected from the M characteristic values for each sample data set, wherein m is an integer larger than 1 and not larger than M. Last, N decision tree models may be respectively built for the N sample data sets based on the m predetermined characteristic values and the initial label of each piece of manufacturing historical data in each sample data set, thereby building the preliminary random forest prediction model.

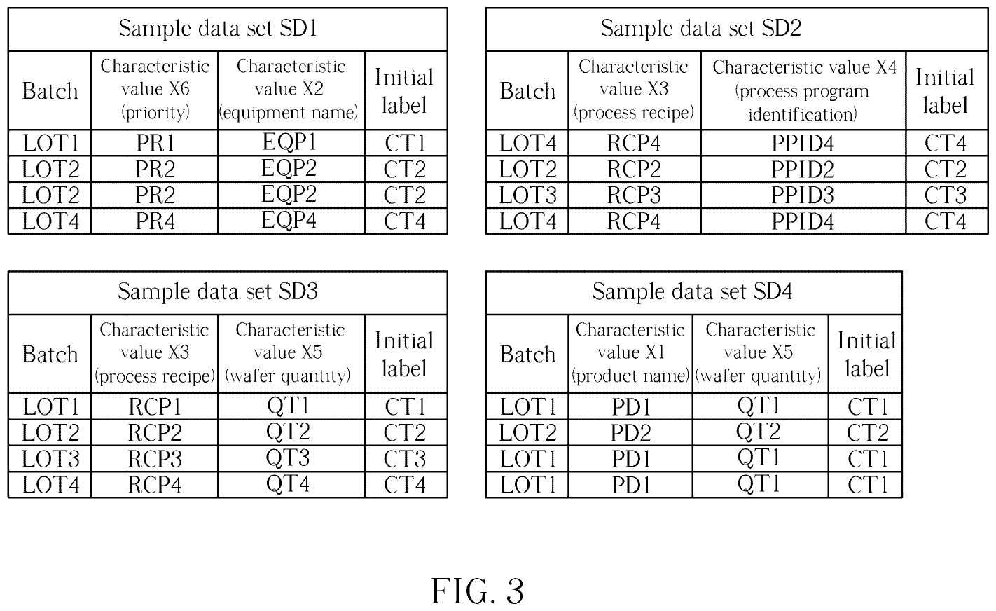

FIG. 3 is a diagram illustrating the sample data sets acquired in step 130 according to an embodiment of the present invention. For illustrative purpose, it is assumed that M=6, m=2, N=4 and n=4. In other words, based on the training data set depicted in FIG. 2, 4 sample data sets SD1-SD4 are selected from the 4 pieces of manufacturing historical data associated with the lots LOT1-LOT4 using a bootstrap aggregating method, wherein each sample data set includes 4 pieces of manufacturing historical data.

In bootstrap aggregating, a random sample data set is made by randomly picking objects from an original dataset with replacement, which means that each item in the original dataset can be selected more than once. For example, the sample data set SD1 sequentially includes 1 piece of manufacturing historical data associated with the lot LOT1, 2 pieces of manufacturing historical data associated with the lot LOT2, and 1 piece of manufacturing historical data associated with the lot LOT4, wherein each piece of the above-mentioned manufacturing historical data includes 2 characteristic values (priority and equipment name) and the initial label of the corresponding lot. The sample data set SD2 sequentially includes 1 piece of manufacturing historical data associated with the lot LOT4, 1 piece of manufacturing historical data associated with the lot LOT2, 1 piece of manufacturing historical data associated with the lot LOT3, and 1 piece of manufacturing historical data associated with the lot LOT4, wherein each piece of the above-mentioned manufacturing historical data includes 2 characteristic values (process recipe and process program identification) and the initial label of the corresponding lot. The sample data set SD3 sequentially includes 1 piece of manufacturing historical data associated with the lot LOT1, 1 piece of manufacturing historical data associated with the lot LOT2, 1 piece of manufacturing historical data associated with the lot LOT3, and 1 piece of manufacturing historical data associated with the lot LOT4, wherein each piece of the above-mentioned manufacturing historical data includes 2 characteristic values (process recipe and wafer quantity) and the initial label of the corresponding lot. The sample data set SD4 sequentially includes 1 piece of manufacturing historical data associated with the lot LOT1, 1 piece of manufacturing historical data associated with the lot LOT2, and 2 pieces of manufacturing historical data associated with the lot LOT2, wherein each piece of the above-mentioned manufacturing historical data includes 2 characteristic values (product name and wafer quantity) and the initial label of the corresponding lot. However, the embodiment of the sample data sets depicted in FIG. 3 are merely for illustrative purposes, and the values of m, N and n do not limit the scope of the present invention.

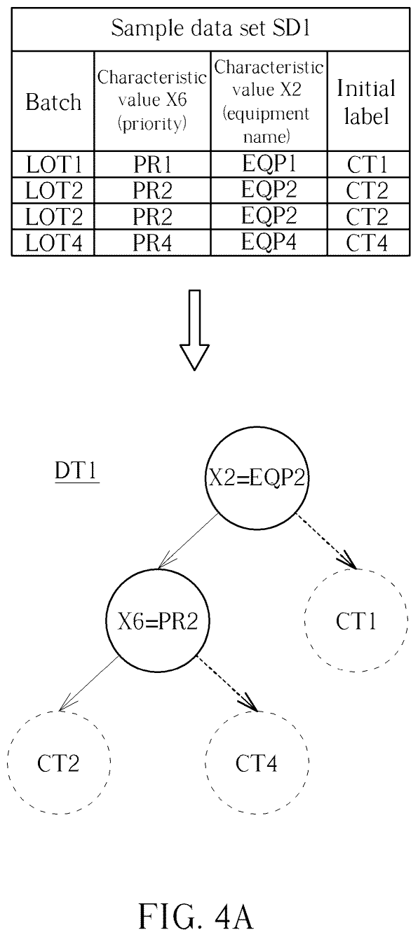

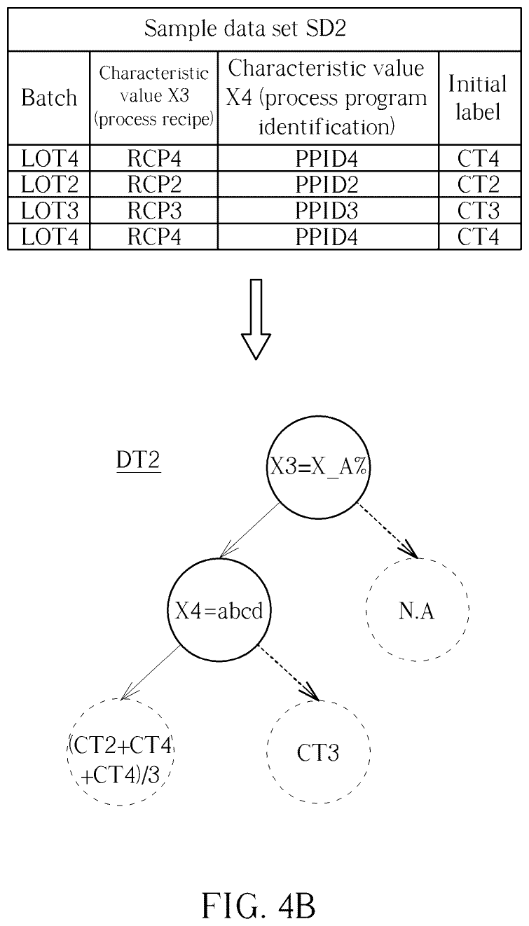

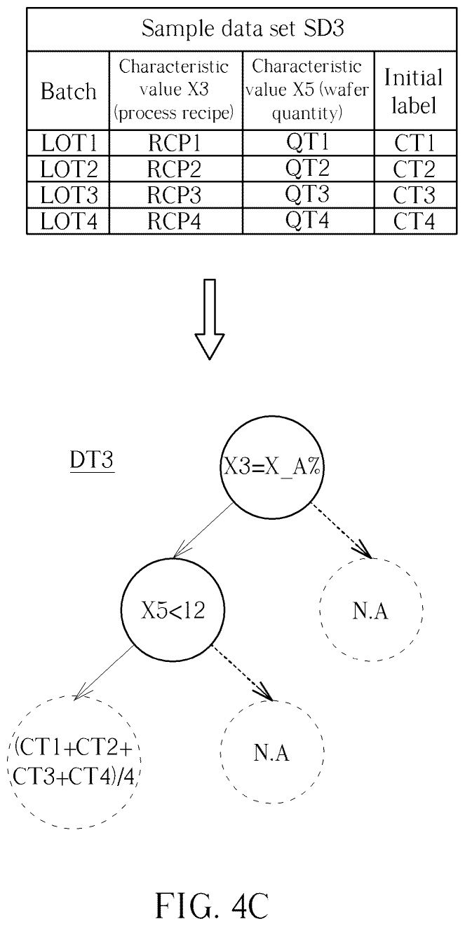

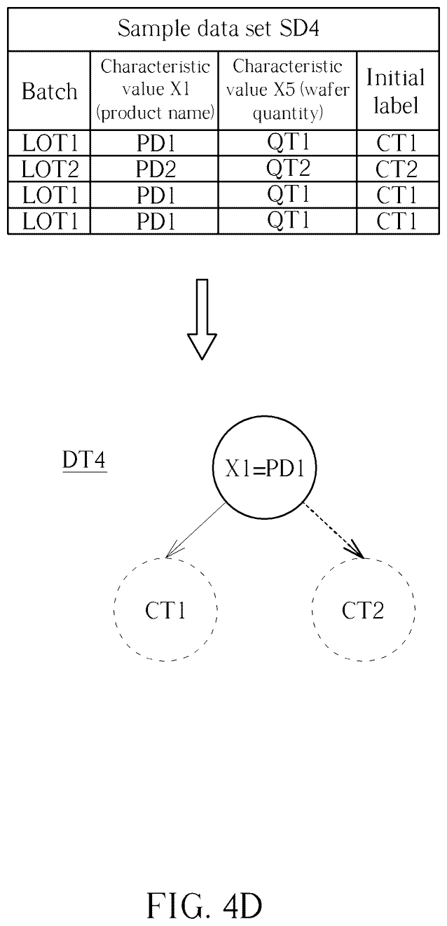

FIGS. 4A-4D are diagrams illustrating decision models DT1-DT4 acquired in step 130 according to an embodiment of the present invention. The decision models DT1-DT4 may be built based on the sample data sets SD1-SD4, respectively. Each solid circle represents a judging node associated with a corresponding characteristic value, each dotted circle represents a leaf node that carries the classification, each solid arrow represents the “Yes” branch, and each dotted arrow represents the “No” branch.

In the present invention, an optimized data splitting criteria associated with each sample data set may be determined based on the information gain of each predetermined characteristic value among the m predetermined characteristic values of each corresponding sample data set. Next, the n pieces of manufacturing historical data of each sample data set may be split using the corresponding m predetermined characteristic values based on the optimized splitting criteria associated with each sample data set, thereby acquiring a decision tree model having multiple judging nodes. For example, the decision tree model DT1 is built based on the 4 pieces of manufacturing historical data of the sample data set SD1, wherein 3 valid prediction results may be generated after splitting data sequentially based on the characteristic values X2 and X6, as depicted in FIG. 4A. The decision tree model DT2 is built based on the 4 pieces of manufacturing historical data of the sample data set SD2, wherein 2 valid prediction results (“N.A” represents an invalid prediction result) may be generated after splitting data sequentially based on the characteristic values X3 and X4, as depicted in FIG. 4B. The decision tree model DT3 is built based on the 4 pieces of manufacturing historical data of the sample data set SD3, wherein 1 valid prediction result (“N.A” represents an invalid prediction result) may be generated after splitting data sequentially based on the characteristic values X3 and X5, as depicted in FIG. 4C. The decision tree model DT4 is built based on the 4 pieces of manufacturing historical data of the sample data set SD4, wherein 2 valid prediction results may be generated after splitting data based on the characteristic value X1, as depicted in FIG. 4D. Therefore, the random forest prediction mode built in step 130 may include 4 decision tree models DT1-DT4.

In step 140, each piece of manufacturing historical data in the testing data set may be inputted into the preliminary random forest prediction model for acquiring the prediction label of each piece of manufacturing historical data in the testing data set.

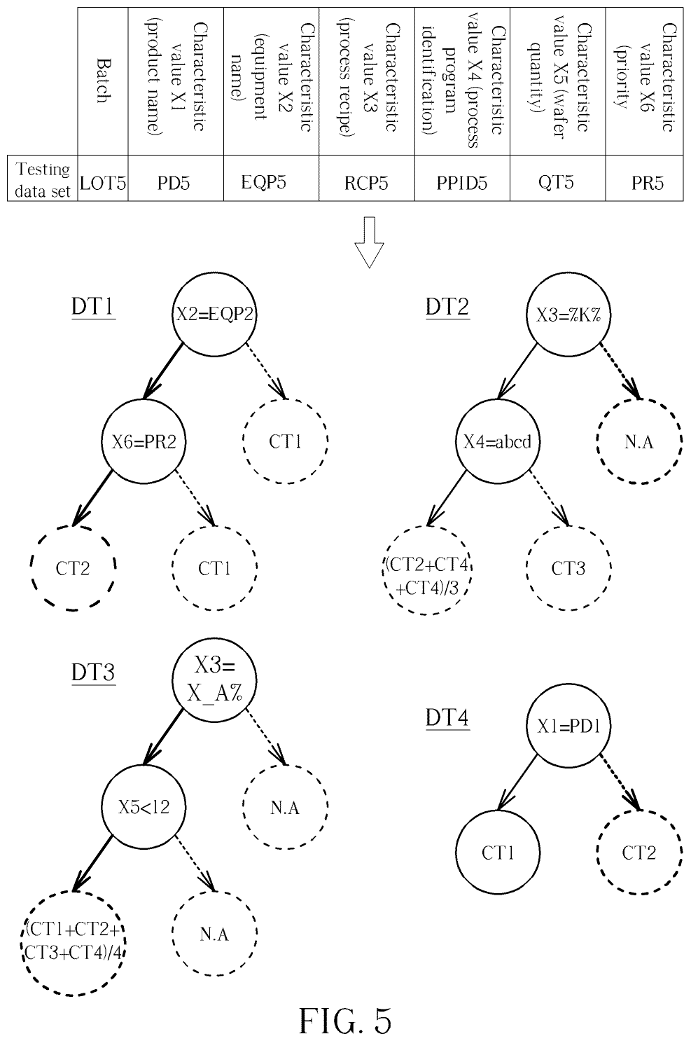

FIG. 5 is a diagram illustrating the prediction label of each piece of manufacturing historical data in the testing data set acquired in step 140 according to an embodiment of the present invention. Also based on the testing data set depicted in FIG. 2 for illustrative purpose, 1 piece of manufacturing historical data associated with the lot LOT5 in the testing data set may be inputted into the decision tree models DT1-DT4, and a prediction label CT5′ of the lot LOT5 may be acquired based on the outputs of the decision tree models DT1-DT4.

Regarding the decision tree model DT1, it is assumed that the lots LOT2 and LOT5 are handled by the same equipment (EQP2=EQP5) and have the same priority (PR2=PR5) during a specific manufacturing step of the manufacturing process. Under such circumstance, the observation of “X2=EQP5” in the input data fits the first judging node “X2-EQP5” and thus will follow the “Yes” branch to move on to the second judging node “X6=PR2”. Next, the observation of “X6=PR5” in the input data fits the second judging node “X6=PR2” and thus will follow the “Yes” branch to move on to the leaf node “CT2”. In other words, after inputting the manufacturing historical data associated with the lot LOT5 into the first decision tree model DT1, the first prediction value outputted by the first decision tree model DT1 is equal to CT2.

Regarding the decision tree model DT2, it is assumed that the lot LOT2 adopts the process recipe PCR5 designated by “% Kg” during the specific manufacturing step. Under such circumstance, the observation of “X3=PCR5” in the input data does not fit the first judging node “X3=X_A %” and thus will follow the “No” branch to move on to the leaf node “N.A”. In other words, after inputting the manufacturing historical data associated with the lot LOT5 into the decision tree model DT2, the second prediction value outputted by the decision tree model DT2 is not a valid value.

Regarding the decision tree model DT3, it is assumed that the lot LOT5 adopts the process recipe PCR5 designated by “X_A %” and includes 10 wafers (QT5=10) during the specific manufacturing step. Under such circumstance, the observation of “X3=RCP5” in the input data fits the first judging node “X3=X_A %” and thus will follow the “Yes” branch to move on to the second judging node “X5<12”. Next, the observation of “X5=QT5” in the input data fits the second judging node “X5<12” and thus will follow the “Yes” branch to move on to the leaf node “CT1+CT2+CT3+CT2/4”. In other words, after inputting the manufacturing historical data associated with the lot LOT5 into the decision tree model DT3, the third prediction value outputted by the decision tree model DT3 is equal to the average value of CT1-CT4.

Regarding the decision tree model DT4, it is assumed that the lots LOT2 and LOT5 produce different products during the specific manufacturing step (PD1≠PD5). Under such circumstance, the observation of “X1=PD5” in the input data does not fit the judging node “X1=PD1” and thus will follow the “No” branch to move on to the leaf node “CT2”. In other words, after inputting the manufacturing historical data associated with the lot LOT5 into the decision tree model DT4, the fourth prediction value outputted by the decision tree model DT4 is equal to CT2.

In the embodiment of a regression model, the present invention may acquire the average of all valid prediction values outputted by all decision tree models as the prediction label of each piece of manufacturing historical data in the testing data set. For example, in the embodiment depicted in FIG. 5, after inputting the manufacturing historical data associated with the lot LOT5 into the decision tree models DT1-DT4, the first prediction value outputted by the decision tree model DT1 is equal to CT2, the second prediction value outputted by the decision tree model DT2 is invalid, the third prediction value outputted by the decision tree model DT3 is equal to (CT1+CT2+CT3+CT4)/4, and the fourth prediction value outputted by the decision tree model DT4 is equal to CT2. Therefore, the prediction label CT5′ of the manufacturing historical data associated with the lot LOT5 may be the average of the first prediction value, the third prediction value and the fourth prediction value.

In the embodiment of a categorical model, the present invention may acquire the mode of all valid prediction values outputted by all decision tree models as the prediction label of each piece of manufacturing historical data in the testing data set. The mode is the value that appears most often in a set of data values. For example, in the embodiment depicted in FIG. 5, after inputting the manufacturing historical data associated with the lot LOT5 into the decision tree models DT1-DT4, the first prediction value outputted by the decision tree model DT1 is equal to CT2, the second prediction value outputted by the decision tree model DT2 is invalid, the third prediction value outputted by the decision tree model DT3 is equal to (CT1+CT2+CT3+CT4)/4, and the fourth prediction value outputted by the decision tree model DT4 is equal to CT2. Therefore, the prediction label CT5′ of the manufacturing historical data associated with the lot LOT5 may be the first prediction value CT2 which appears most often in all valid prediction values.

In steps 150 and 160, the optimized random forest prediction model may be acquired based on the initial label and the prediction label of each piece of manufacturing historical data in the testing data set. More specifically, it is determined in step 150 whether the preliminary random forest prediction model is an optimized random forest prediction model by comparing the initial label and the prediction label of each piece of manufacturing historical data in the testing data set. If the initial label of each piece of manufacturing historical data in the testing data set matches the prediction label of each corresponding piece of manufacturing historical data in the testing data set, it is determined that the preliminary random forest prediction model has been optimized and the current preliminary random forest prediction model is thus set as the optimized random forest prediction model. If the initial label of each piece of manufacturing historical data in the testing data set does not match the prediction label of each corresponding piece of manufacturing historical data in the testing data set, it is determined that the preliminary random forest prediction model has not been optimized and the current preliminary random forest prediction model is thus optimized in step 160 before looping back to step 140. Steps 140-160 may be repeatedly executed until it is determined in step 150 that the preliminary random forest prediction model has been optimized.

Also based on the embodiments depicted in FIGS. 2 and 5 for illustrative purpose, if the prediction label CT5′ of the manufacturing historical data associated the lot LOT5 matches the initial label CT5 of the manufacturing historical data associated the lot LOT5, it is determined in step 150 that the preliminary random forest prediction model is the optimized random forest prediction model, and step 170 is then executed. If the prediction label CT5′ of the manufacturing historical data associated the lot LOT5 does not match the initial label CT5 of the manufacturing historical data associated the lot LOT5, it is determined in step 150 that the preliminary random forest prediction model is not the optimized random forest prediction model. Under such circumstance, step 160 is then executed for adjusting the parameters of the preliminary random forest prediction model. After repeatedly executing steps 140-160 until it is determined in step 150 that the preliminary random forest prediction model has been optimized, step 170 is then executed.

In step 160, the present invention may optimize the preliminary random forest prediction model by adjusting the parameters of the preliminary random forest prediction model. For example, the maximum depth, the minimum sample split and/or the minimum leaf sample node count of the preliminary random forest prediction model may be adjusted in step 160 for reducing over-fitting (when a model's complexity is insufficient for the dataset, resulting in a hypothesis that is overly simplistic and inaccurate) or under-fitting (when a model may generate precise predictions, but its initial assumptions regarding the data are not correct). However, the method of optimizing the preliminary random forest prediction model does not limit the scope of the present invention.

In step 170, new data may be inputted into the optimized random forest prediction model for acquiring an estimated start time and/or an estimated end time of each manufacturing step in the manufacturing process.

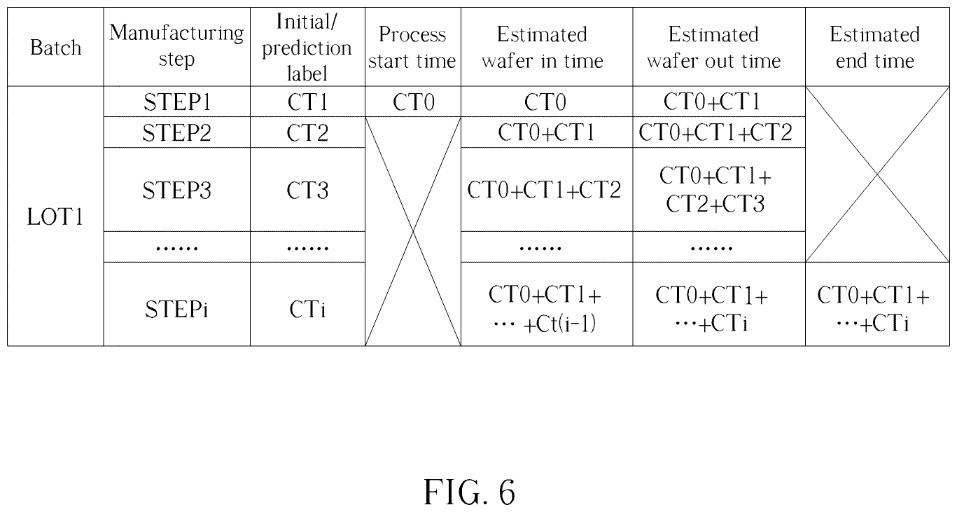

FIG. 6 is a diagram illustrating the estimated start time and/or the estimated end time of each manufacturing step in the manufacturing process acquired in step 170 according to an embodiment of the present invention. For the manufacturing historical data associated with the lot LOT1 collected during i manufacturing steps of the manufacturing process (i is an integer larger than 1), the estimated start time and the estimated end time of each manufacturing step acquired after executing steps 120-160 may be represented by the following formula:

$$Estimated start time = process start time + {\sum }_{S = 1}^{i - 1} CTs$$

$$Estimated end time = process start time + {\sum }_{S = 1}^{i} CTs$$

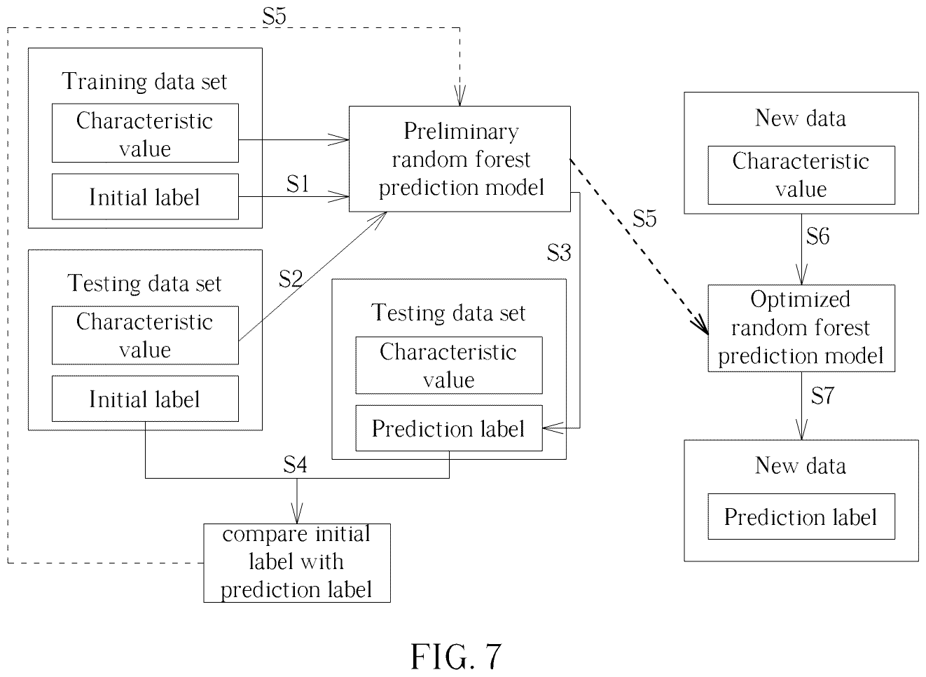

FIG. 7 is a state diagram illustrating each stage when performing the present method of predicting wafer out time according to an embodiment of the present invention. State S1 is associated with building the preliminary prediction model and corresponds to step 130 depicted in FIG. 1. States S2-S4 are associated with evaluating the preliminary prediction model and correspond to steps 140-150 depicted in FIG. 1. State S5 is associated with optimizing the preliminary prediction model and corresponds to step 160 depicted in FIG. 1. States S6-S7 are associated with predicting new data based on the optimized prediction model and correspond to step 170 depicted in FIG. 1.

In conclusion, based on the manufacturing data set associated with each lot collected during each manufacturing step of a manufacturing process, a preliminary random forest prediction model may be built based on characteristic values and an initial label of each piece of manufacturing historical data in the training data set. Next, an optimized random forest prediction model associated with the preliminary random forest prediction model may be built based on each piece of manufacturing historical data in the testing data set. Last, new data may be inputted into the optimized random forest prediction model for acquiring the estimated start time and/or the estimated end time of each manufacturing step in the manufacturing process. Therefore, the present invention cam optimize the wafer casting arrangement and wafer out procedure, as well as reduce the cost of human maintenance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of predicting wafer out time, comprising:
collecting manufacturing historical data of each lot during each manufacturing step of a manufacturing process for providing a manufacturing data set;
dividing the manufacturing data set into a training data set and a testing data set;
building a preliminary random forest prediction model based on M characteristic values and an initial label of each piece of manufacturing historical data in the training data set, wherein M is an integer larger than 1;
inputting each piece of manufacturing historical data in the testing data set into the preliminary random forest prediction model for acquiring a prediction label of each piece of manufacturing historical data in the testing data set;
building an optimized random forest prediction model associated with the preliminary random forest prediction model based on the initial label and the prediction label of each piece of manufacturing historical data in the testing data set; and
inputting new data into the optimized random forest prediction model for acquiring an estimated start time and/or an estimated end time of each lot during each manufacturing step in the manufacturing process.

2. The method of claim 1, further comprising:
selecting N sample data sets from the training data set using a bootstrap aggregating method, wherein:
each sample data set includes n pieces of manufacturing historical data;
N is an integer larger than 1; and
n is an integer larger than 1.

3. The method of claim 2, further comprising:
selecting m predetermined characteristic values from the M characteristic values for each sample data set, wherein m is an integer larger than 1 and not larger than M.

4. The method of claim 3, further comprising:
building N decision tree models respectively for the N sample data sets based on the m predetermined characteristic values and the initial label of each piece of manufacturing historical data in each sample data set, thereby building the preliminary random forest prediction model;
inputting each piece of manufacturing historical data in the testing data set into the N decision tree models for acquiring N1 prediction values; and
acquiring an average value of the N1 prediction values as the prediction label of each piece of manufacturing historical data in the testing data set.

5. The method of claim 4, wherein:
N1 is a positive integer not larger than N; and
each of the N1 prediction values is a valid value.

6. The method of claim 3, further comprising:
building N decision tree models respectively for the N sample data sets based on the m predetermined characteristic values and the initial label of each piece of manufacturing historical data in each sample data set, thereby building the preliminary random forest prediction model;
inputting each piece of manufacturing historical data in the testing data set into the N decision tree models for acquiring N1 prediction values; and
acquiring a mode of the N1 prediction values as the prediction label of each piece of manufacturing historical data in the testing data set.

7. The method of claim 6, wherein:
N1 is a positive integer not larger than N; and
each of the N1 prediction values is a valid value.

8. The method of claim 3, further comprising:
acquiring an optimized data splitting criteria associated with each sample data set based on an information gain of each predetermined characteristic value among the m predetermined characteristic values of each sample data set; and
splitting the n pieces of manufacturing historical data in each sample data set using the corresponding m predetermined characteristic values based on the optimized data splitting criteria associated with each sample data set, thereby acquiring a decision tree model having multiple judging nodes.

9. The method of claim 1, wherein:
the training data set includes A pieces of manufacturing historical data;
the testing data set includes B pieces of manufacturing historical data;
A and B are integers larger than 1; and
A is larger than B.

10. The method of claim 1, further comprising:
performing a dummy variable processing on each piece of manufacturing historical data in the manufacturing data set.

11. The method of claim 1, further comprising:
performing a data normalization processing on each piece of manufacturing historical data in the manufacturing data set.

12. The method of claim 1, further comprising:
adjusting a parameter of the preliminary random forest prediction model for acquiring the optimized random forest prediction model when determining that the prediction label of each piece of manufacturing historical data in the testing data set does not match the initial label of each piece of manufacturing historical data in the testing data set.

13. The method of claim 12, wherein the parameter of the preliminary random forest prediction model includes a maximum depth, a minimum sample split or a minimum leaf sample node count of the preliminary random forest prediction model.

14. The method of claim 1, wherein:
an estimated process end time of a specific lot is equal to a sum of a start time of the manufacturing process and the initial label or the prediction label of the specific lot during each manufacturing step of the manufacturing process.
